(19) United States
(12) Patent Application Publication
(10) Pub. No.: US 2014/0030873 A1
(43) Pub. Date: Jan. 30, 2014

(54) METHOD FOR FABRICATING PATTERNED SILICON NANOWIRE ARRAY AND SILICON MICROSTRUCTURE

(71) Applicant: National Taiwan University of Science and Technology, (US)

(72) Inventors: Yung-jr HUNG, Taipei City (TW); San-liang LEE, Taipei City (TW)

(73) Assignee: National Taiwan University of Science and Technology, Taipei City (TW)

(21) Appl. No.: 13/680,301

(22) Filed: Nov. 19, 2012

(30) Foreign Application Priority Data
Jul. 27, 2012 (TW) 101127311

(51) Int. Cl. H01L 21/306; H01L 21/20

(52) U.S. Cl. CPC H01L 21/30604; H01L 21/20
USPC 438/478; 438/694

(57) ABSTRACT

A method for fabricating a patterned silicon nanowire array is disclosed. The method includes: forming a patterned protective layer on silicon nanowire array structures, forming a patterned protective layer on the array of silicon nanowire structures, the patterned protective layer defining a covered region and a uncovered region on the array of silicon nanowire structures; using a selective etching to remove the array of silicon nanowire structures defined on the uncovered region; and removing the patterned protective layer remained on the array of silicon nanowire structures. A method for fabricating a silicon microstructure is also disclosed.

### CROSS-REFERENCE

This application claims the priority of Taiwan Patent Application No. 101127311, filed on Jul. 27, 2012. This invention is partly disclosed in papers: 1) “International Electron Devices and Materials Symposium (IEDMS), paper D4-4, Taiwan, Nov. 17-18, 2011,” entitled “Vertically-aligned silicon nanowire bundles for field emission applications” completed by Looi Choon Beng, Yung-Jr Hung, San-Liang Lee, Kuei-Yi Lee, Kai-Chung Wu, and Yen-Ting Pan. 2) “2012 the Conference on Lasers and Electro-Optics (CLEO), Paper CTh1C.5, San Jose, Calif., USA, May 6-11, 2012,” entitled “Top-down formation of vertically-aligned silicon nanowire bundles for tuning optical and field emission properties” completed by completed by Yung-Jr Hung, San-Liang Lee, Looi Choon Beng, Soo Chee Yeng, and Kuei-Yi Lee. 3) “Journal of Vacuum Science and Technology B, vol. 30, no. 3, pp. 030604-1˜030604-7, May/June 2012,” entitled “Formation of mesa-type vertically-aligned silicon nanowire bundle arrays by selective-area chemical oxidation and etching processes” completed by Yung-Jr Hung, San-Liang Lee and Looi Choon Beng.

### TECHNICAL FIELD OF THE INVENTION

The present invention relates to a method for fabricating silicon nanowires, especially to a method for fabricating a patterned silicon nanowire array and silicon microstructures.

### BACKGROUND OF THE INVENTION

Silicon nanowire (SiNW) arrays have an optical-antireflective surface, and it can be applied to surfaces of solar cells for effectively enhancing absorption of sunlight. Conventionally, the silicon nanowire (SiNW) arrays are defined by lithography-related process such as photolithography, interference lithography, and sphere lithography, and then are transferred into silicon by dry etching. However, the manufacturing cost thereof is higher, and it is difficult to fabricate the silicon nanowire array uniformly over a large area for solar panel applications. As a result, fabrication method of the larger-area silicon nanowire arrays is gradually shifted to non-lithography processes, e.g. by growth of the silicon nanowires, a metal-induced silicon etching, and so on.

Moreover, if the silicon nanowires are only required to be formed on a partial region, that is, to be a patterned silicon nanowire array, the most common method is to fabricate by crystal growth. The manner of the so-called crystal growth is to define catalyst particles formed on the partial region by photolithography technology first, and then to form the patterned silicon nanowire array by the crystal growth. However, the manner of the single-crystalline growth requires a high-temperature ambient condition above 1000° C. for the growth, so the cost of the fabrication is extremely high.

At present, in other methods to fabricate the patterned silicon nanowire array, there is still a manner to fabricate a silicon bench by the photolithography technology first and then to fabricate a protective layer around the silicon bench and subsequently to etch the silicon bench. However, the processes of this fabrication manner are complex, and quality of the patterned silicon nanowire array made thereby is poor.

Accordingly, there is an urgent need to improve the conventional technology for overcoming the drawback that the patterned silicon nanowire array is difficult to be fabricated in the prior art.

### SUMMARY OF THE INVENTION

An objective of the present invention is to provide a method for fabricating a patterned silicon nanowire array, which is to form a patterned protective layer on silicon nanowire array structures and then etch the silicon nanowires which are not protected, thereby forming the patterned silicon nanowire array.

Another objective of the present invention is to provide a method for fabricating a patterned silicon nanowire array, which is capable of forming heterostructures on said patterned silicon nanowire array for applying to a field emission display.

Yet another objective of the present invention is to provide a method for fabricating a silicon microstructure, which is capable of forming a partial silicon nanowire array on a silicon substrate and then etching the silicon nanowires for achieving the objective that the silicon microstructures with vertical sidewalls can be made by wet etching for any silicon substrate, especially for (100) monocrystalline silicon.

To achieve the foregoing objectives, the present invention provides a method for fabricating a patterned silicon nanowire array. The method includes: forming an array of silicon nanowire structures; forming a patterned protective layer on the array of silicon nanowire structures, the patterned protective layer defining a covered region and a uncovered region on the array of silicon nanowire structures; using a selective etching to remove the array of silicon nanowire structures defined on the uncovered region; and removing the patterned protective layer remained on the array of silicon nanowire structures.

In the fabrication method, the step of forming the array of silicon nanowire structures includes: forming a metal layer with a predetermined thickness on a silicon substrate by a coating process; performing a metal-induced chemical etching for the silicon substrate by using an etching solution; rinsing the metal layer from the silicon substrate.

In one preferred embodiment, the step of forming the patterned protective layer includes: oxidizing the array of silicon nanowire structures forming an oxide layer on a surface of the array of silicon nanowire structures; and patterning the oxide layer so that the array of silicon nanowire structures have the oxide layer on the covered region and expose a plurality of silicon nanowires on the uncovered region. Specifically, the step of oxidizing the array of silicon nanowire structures includes immersing the array of silicon nanowire structures in a nitric acid solution. The step of patterning the oxide layer comprises a photolithography process. In addition, the step of the selective etching includes: immersing the array of silicon nanowire structures which have the oxide layer in a potassium hydroxide (KOH) solution, so as to etch the silicon nanowires exposed on the uncovered region of the array of silicon nanowire structures. Preferably, the KOH solution includes about 60% by weight of potassium hydroxide at room temperature.

In another preferred embodiment, the step of forming the patterned protective layer includes: coating a photoresist layer over the array of silicon nanowire structures, wherein space between a plurality of silicon nanowires is filled with the photoresist layer; and patterning the photoresist layer so that the array of silicon nanowire structures have the photoresist layer on the covered region and simultaneously expose the silicon nanowires on the uncovered region. Specifically, the step of patterning the photoresist layer comprises an exposure process and a develop process. In addition, the step of the selective etching includes: immersing the array of silicon nanowire structures which have the photoresist layer in an aqueous solution containing hydrofluoric acid and nitric acid, so as to etch the silicon nanowires exposed on the uncovered region of the array of silicon nanowire structures.

To achieve the foregoing objectives, the present invention provides a method for fabricating heterojunctions on a patterned silicon nanowire array. The method includes: forming an array of silicon nanowire structures; depositing a catalyst layer on the array of silicon nanowire structures; forming a patterned protective layer on the array of silicon nanowire structures having the catalyst layer, the patterned protective layer defining a covered region and a uncovered region on the array of silicon nanowire structures; using a selective etching to remove the catalyst layer and the array of silicon nanowire structures defined on the uncovered region; removing the patterned protective layer remained on the array of silicon nanowire structures to form the patterned silicon nanowire array; and growing a plurality of heterostructures on the patterned silicon nanowire array.

In the fabrication method, the step of forming the array of silicon nanowire structures includes: forming a metal layer with a predetermined thickness on a silicon substrate by a coating process; performing a metal-induced chemical etching for the silicon substrate by using an etching solution; and rinsing the metal layer from the silicon substrate.

In one preferred embodiment, It is worth mentioning that the catalyst layer is just formed on tops of a plurality of silicon nanowires of the array of silicon nanowire structures. In addition, the step of forming the patterned protective layer includes: coating a photoresist layer over the array of silicon nanowire structures having the catalyst layer, wherein space between the silicon nanowires is filled with the photoresist layer; and patterning the photoresist layer so that the array of silicon nanowire structures has the photoresist layer on the covered region and simultaneously expose the silicon nanowires having the catalyst layer on the uncovered region. The step of the selective etching includes: removing the catalyst layer positioned on the uncovered region; and immersing the array of silicon nanowire structures which have the photoresist layer in an aqueous solution containing hydrofluoric acid and nitric acid, so as to etch the silicon nanowires exposed on the uncovered region of the array of silicon nanowire structures.

In one preferred embodiment, the heterostructures are a plurality of carbon nanotubes, and the carbon nanotubes grow through a thermal chemical vapor deposition.

To achieve the foregoing objectives, the present invention provides a method for fabricating a silicon microstructure. The method includes: forming a patterned photoresist layer on a silicon substrate, the patterned photoresist layer having a covered region and a uncovered region on the silicon substrate; forming a metal layer with a predetermined thickness on the silicon substrate having the patterned photoresist layer by a coating process; performing a metal-induced chemical etching for the silicon substrate positioned on the uncovered region by using an etching solution; rinsing the metal layer from the silicon substrate for forming a silicon nanowire array on the uncovered region; and performing a chemical wet etching to remove the silicon nanowire array formed on the uncovered region.

In one preferred embodiment, the predetermined thickness is between 5 and 50 nanometers. In addition, the silicon substrate is made of monocrystalline silicon, polycrystalline silicon, or amorphous silicon. Preferably, the silicon substrate is made of monocrystalline silicon which has a lattice plane of 100.

In accordance with the fabrication method of the patterned silicon nanowire arrays of the present invention, the oxide layer or the patterned protective layer implemented by the photoresist layer is directly formed between the array of silicon nanowire structures, and then the silicon nanowires which are not protected are etched by the wet etching, thereby easily and low-costly manufacturing the patterned silicon nanowire array. In addition, the present invention is further capable of forming the heterostructures, e.g. growing the carbon nanotubes, on said patterned silicon nanowire array for applying to electrical field emission applications. Finally, the present invention is capable of forming the partial silicon nanowire array on the silicon substrate and then etching the silicon nanowires for achieving the objective that the silicon microstructures with vertical sidewalls can be made by wet etching for any silicon substrate, especially for the (100) monocrystalline silicon.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a flow chart illustrating a method for fabricating a patterned silicon nanowire array;

FIG. 2 is a flow chart illustrating detailed steps of step S10;

FIG. 3 is a schematic section view illustrating a silicon substrate in performing step S11;

FIG. 4 is a schematic section view illustrating the silicon substrate in performing step S12;

FIG. 5 is a schematic section view illustrating the silicon substrate in performing step S13;

FIG. 6 is a flow chart illustrating processes of forming a patterned protective layer according to the first preferred embodiment;

FIG. 7 is a schematic section view illustrating an array of silicon nanowire structures in performing step S21;

FIG. 8 is a schematic section view illustrating the array of silicon nanowire structures in performing step S22;

FIG. 9 is a schematic section view illustrating the array of silicon nanowire structures in performing step S30 according to the first preferred embodiment;

FIG. 10 is a schematic section view illustrating the array of silicon nanowire structures in performing step S40 according to the first preferred embodiment;

FIG. 11 is a flow chart illustrating processes of forming a patterned protective layer according to the second preferred embodiment;

FIG. 12 is a schematic section view illustrating the array of silicon nanowire structures in performing step S23;

FIG. 13 is a schematic section view illustrating the array of silicon nanowire structures in performing step S24;

FIG. 14 is a schematic section view illustrating the array of silicon nanowire structures in performing step S30 according to the second preferred embodiment;

FIG. 15 is a schematic section view illustrating the array of silicon nanowire structures in performing step S40 according to the second preferred embodiment;

FIG. 16 depicts a flow chart illustrating a fabrication method of forming heterostructures on the patterned silicon nanowire array according to the preferred embodiment of the present invention;

FIG. 17 is a schematic section view illustrating the array of silicon nanowire structures in performing step S20′;

FIG. 18 is a flow chart illustrating processes of forming the patterned protective layer according to the preferred embodiment;

FIG. 19 is a schematic section view illustrating the array of silicon nanowire structures in performing step S31;

FIG. 20 is a schematic section view illustrating the array of silicon nanowire structures in performing step S32;

FIG. 21 is a schematic section view illustrating the array of silicon nanowire structures in performing step S40′ according to the preferred embodiment;

FIG. 22 is a schematic section view illustrating the array of silicon nanowire structures in performing step S50′ according to the preferred embodiment;

FIG. 23 is a schematic section view illustrating the array of silicon nanowire structures in performing step S60′ according to the preferred embodiment;

FIG. 24 is a flow chart illustrating a method for fabricating a silicon microstructure according to one preferred embodiment of the present invention;

FIG. 25 is a schematic section view illustrating the silicon substrate in performing step S10″;

FIG. 26 is a schematic section view illustrating the silicon substrate in performing step S20″;

FIG. 27 is a schematic section view illustrating the silicon substrate in performing step S30″;

FIG. 28 is a schematic section view illustrating the silicon substrate in performing step S40″;

FIG. 29 is a schematic section view illustrating the silicon substrate in performing step S50″; and

FIG. 30 is a schematic section view illustrating the silicon substrate in performing step S60″.

### DETAILED DESCRIPTION OF THE INVENTION

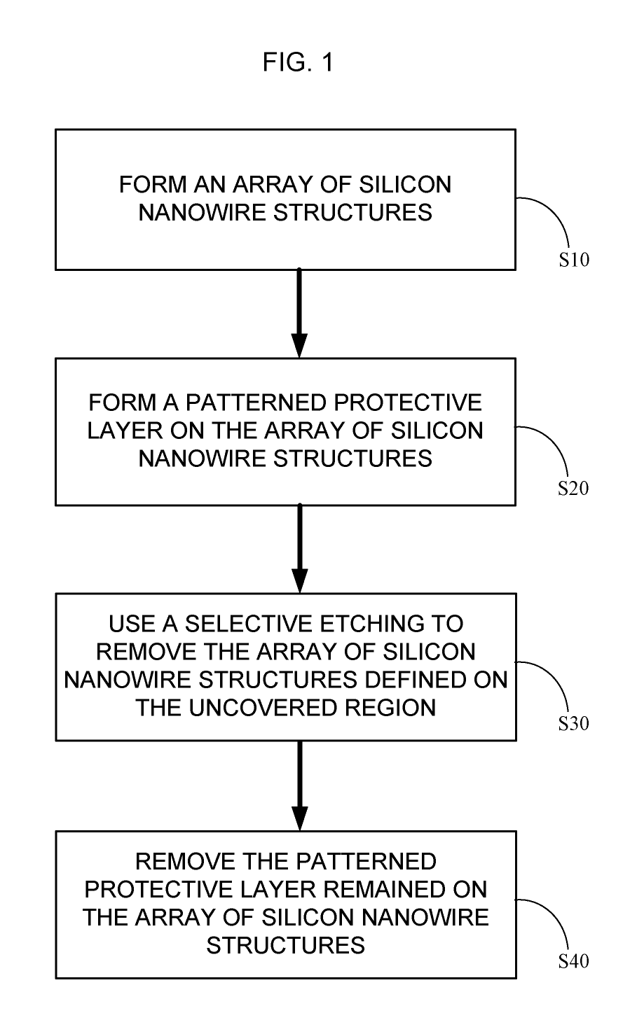

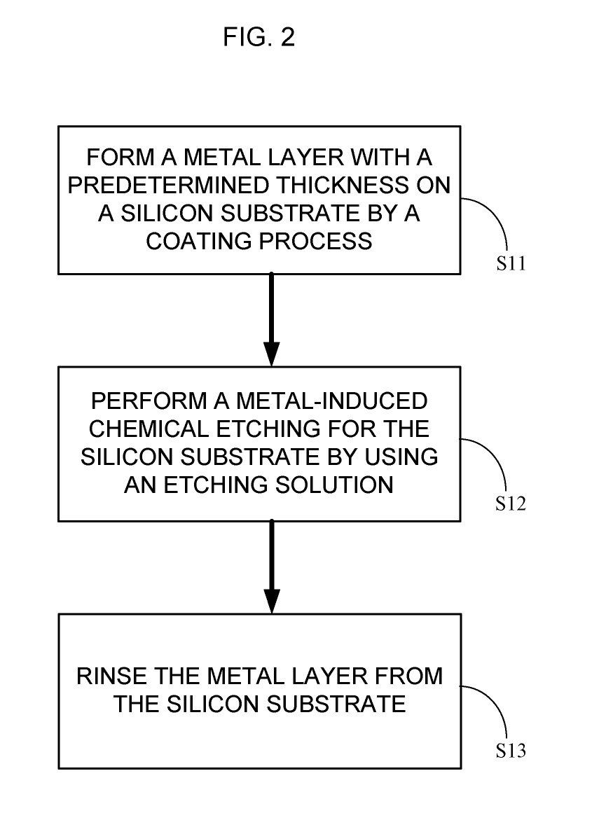

The following will explain a method for fabricating a patterned silicon nanowire array according to a preferred embodiment of the present invention in detail with drawings. Referring to FIG. 1 and FIG. 2, FIG. 1 is a flow chart illustrating a method for fabricating a patterned silicon nanowire array; FIG. 2 is a flow chart illustrating detailed steps of step S10. The fabrication method of the embodiment begins with step S10.

At step S10, silicon nanowire array structures are formed. As shown in FIG. 2, the step of forming the array of silicon nanowire structures begins with step S11. Referring to FIG. 3, FIG. 3 is a schematic section view illustrating a silicon substrate in performing step S11. Specifically, the array of silicon nanowire structures means the silicon nanowires with large area and uniform arrangement made on a silicon substrate 10. It should be noted that the silicon substrate 10 is a substrate which has a silicon layer on the surface thereof. The silicon material can be monocrystalline silicon, which has a lattice plane of 100, 110, or 111, for example. The silicon material also can be polycrystalline silicon or amorphous silicon (a-Si); moreover, the silicon material is intrinsic silicon or doped silicon.

At step S11, a metal layer 20 with a predetermined thickness is formed on the silicon substrate 10 by a coating process. The material of the metal layer 20 is selected from the group consisting of silver (Ag), gold (Au), and platinum (Pt), in which the silver (Ag), gold (Au), and platinum (Pt) are the metals having a catalytic effect for the silicon. Specifically, the coating process can be electron beam evaporation, physical vapor deposition, chemical vapor deposition, sputtering, and so on. In the preferred embodiment, the metal layer is silver, and the predetermined thickness of the metal layer 20 is between 5 and 50 nanometers (nm). In the preferred embodiment, the best thickness of the metal layer 20 is 20 nanometers (nm).

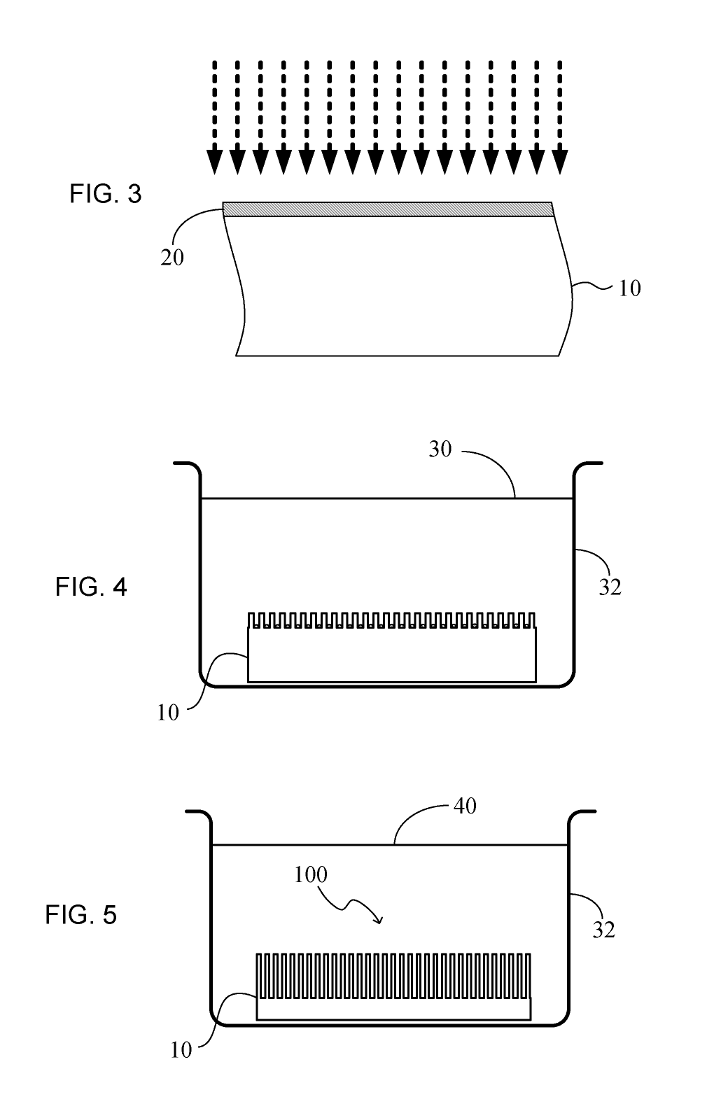

Referring to FIG. 2 and FIG. 4, FIG. 4 is a schematic section view illustrating the silicon substrate 10 in performing step S12. At step S12, an etching solution 30 is utilized to perform a metal-induced chemical etching for the silicon substrate 10. In the preferred embodiment, the step S12 is to immerse the silicon substrate 10 in a container 32 with the etching solution 30 for processing a wet etching.

Specifically, the etching solution 30 can be an aqueous solution of hydrogen fluoride (HF) and hydrogen peroxide (H₂O₂), that is, hydrofluoric acid mixed with hydrogen peroxide. Because the thickness of the metal layer 20 is ultra thin (5 nm to 50 nm), the etching solution 30 can easily be infiltrated to the surface of the silicon substrate 10. Furthermore, the silicon substrate 10 is partially etched down through the catalyst of the silver at the area on which the silver is located, and the area uncovered by the silver is not etched down. The hydrogen peroxide (H₂O₂) is utilized to oxidize the silicon to form silicon dioxide (SiO₂) underneath the silver, and then the hydrofluoric acid is utilized to etch the silicon dioxide (SiO₂), thereby etching down.

Referring to FIG. 2 and FIG. 5, FIG. 5 is a schematic section view illustrating the silicon substrate 10 in performing step S13. At step S13, the metal layer 20 is rinsed from the silicon substrate 10. For example, the remaining silver can be washed away by using nitric acid (HNO₃) solution 40 forming the array 100 of silicon nanowire structures with clean and uniform arrangement over the large area.

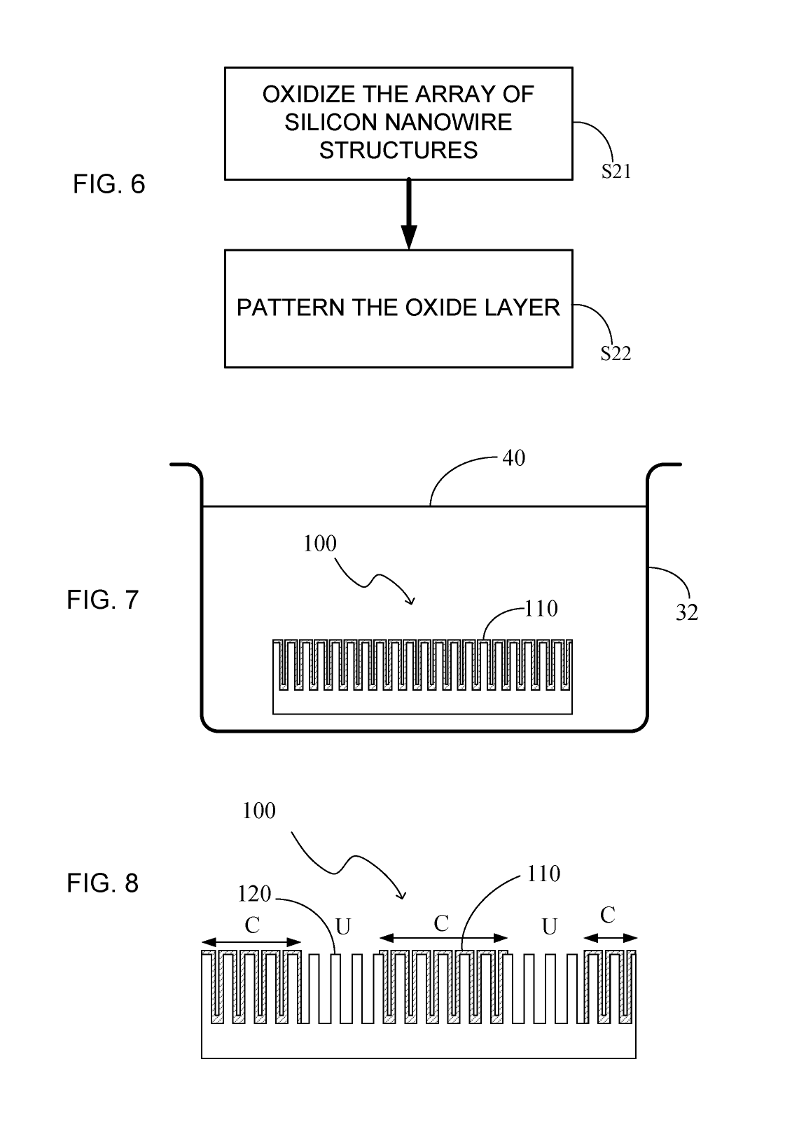

Referring to FIG. 1 again, at step S20, a patterned protective layer is formed on the array 100 of silicon nanowire structures, and the patterned protective layer defines a covered region and a uncovered region on the array 100 of silicon nanowire structures. The following will explain a method for fabricating a patterned silicon nanowire array according to a first preferred embodiment of the present invention in detail with FIG. 6. FIG. 6 is a flow chart illustrating processes of forming the patterned protective layer according to the first preferred embodiment. In the first preferred embodiment, the step of forming the patterned protective layer begins with step S21.

Referring to FIG. 6 and FIG. 7, FIG. 7 is a schematic section view illustrating the array 100 of silicon nanowire structures in performing step S21. At step S21, the array 100 of silicon nanowire structures will be oxidized forming an oxide layer 110 on a surface of the array 100 of silicon nanowire structures. In the embodiment, the array 100 of silicon nanowire structures is immersed in nitric acid solution 40 at 120 degrees for half an hour. Under this condition, the thickness of the oxide layer 110 is about 1 nm to 2 nm.

Referring to FIG. 6 and FIG. 8, FIG. 8 is a schematic section view illustrating the array 100 of silicon nanowire structures in performing step S22. At step S22, the oxide layer 110 is patterned so that the array 100 of silicon nanowire structures have the oxide layer 110 on the covered region C and expose a plurality of silicon nanowires 120 on the uncovered region U. Specifically, the step of patterning the oxide layer may include a conventional photolithography process. For example, the processes includes to define the covered region C by a photoresist, and then to immerse it in hydrofluoric (HF) acid for removing the oxide layer 110 located on the uncovered region U, and finally to remove the photoresist.

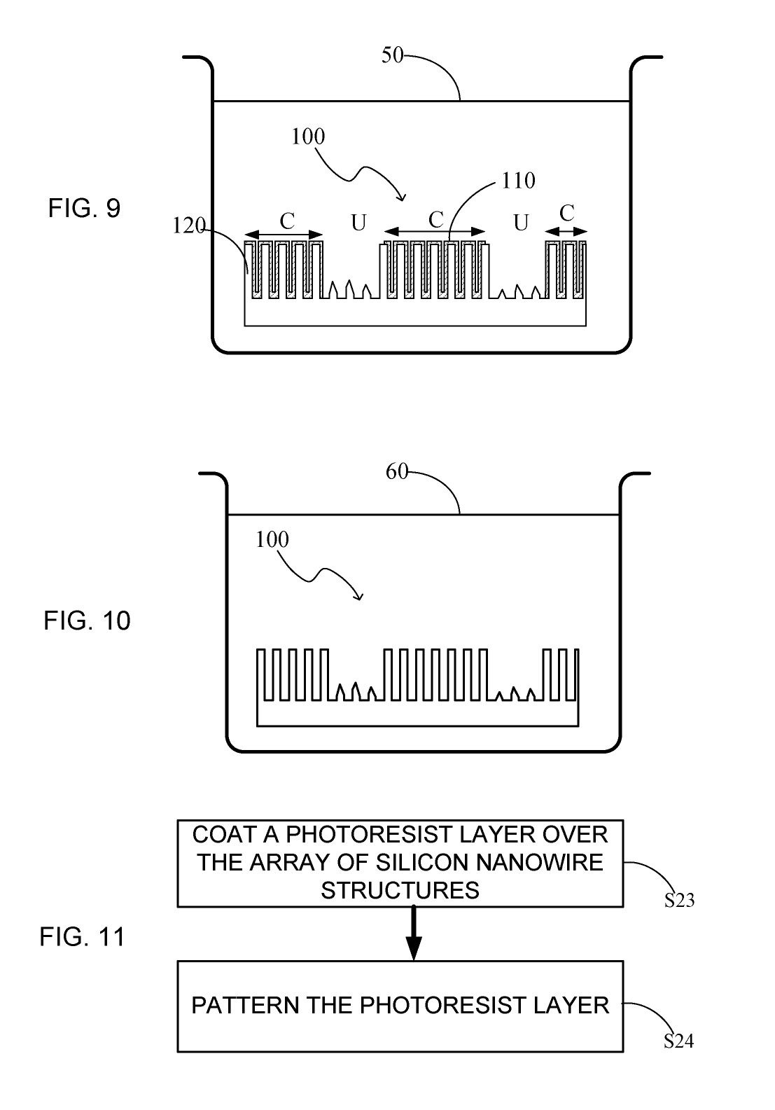

Referring to FIG. 1 again, at step S30, a selective etching is employed to remove the array 100 of silicon nanowire structures defined on the uncovered region U. Referring to FIG. 9, FIG. 9 is a schematic section view illustrating the array 100 of silicon nanowire structures in performing step S30 according to the first preferred embodiment. In the first preferred embodiment, the step of the selective etching specifically includes immersing the array 100 of silicon nanowire structures which have the oxide layer 110 in a potassium hydroxide (KOH) solution 50, so as to etch the silicon nanowires 120 exposed on the uncovered region U of the array 100 of silicon nanowire structures. More specifically, the KOH solution has about 60% by weight of potassium hydroxide, and immersing time is preferably 90 seconds at room temperature.

It is worth mentioning that the oxide layer 110 enables the protection against the KOH solution 50, and the KOH solution 50 has an anisotropic etching reaction for the silicon nanowires 120. Thus, the silicon nanowires 120 after etching may remain some tip structures.

Referring to FIG. 1 and FIG. 10, FIG. 10 is a schematic section view illustrating the array 100 of silicon nanowire structures in performing step S40 according to the first preferred embodiment. At step S40, the patterned protective layer remained on the array 100 of silicon nanowire structures is removed. In the first preferred embodiment, the array 100 of silicon nanowire structures is immersed in a hydrofluoric acid solution 60 to remove the remaining oxide layer 100, thereby completing the patterned silicon nanowire array.

The following will explain the method for fabricating a patterned silicon nanowire array according to the second preferred embodiment of the present invention in detail with FIGS. 1 and 11. At step S20, a patterned protective layer is formed on the array 100 of silicon nanowire structures, and the patterned protective layer defines a covered region and a uncovered region on the array 100 of silicon nanowire structures. FIG. 11 is a flow chart illustrating processes of forming the patterned protective layer according to the second preferred embodiment. In the second preferred embodiment, the step of forming the patterned protective layer begins with step S23.

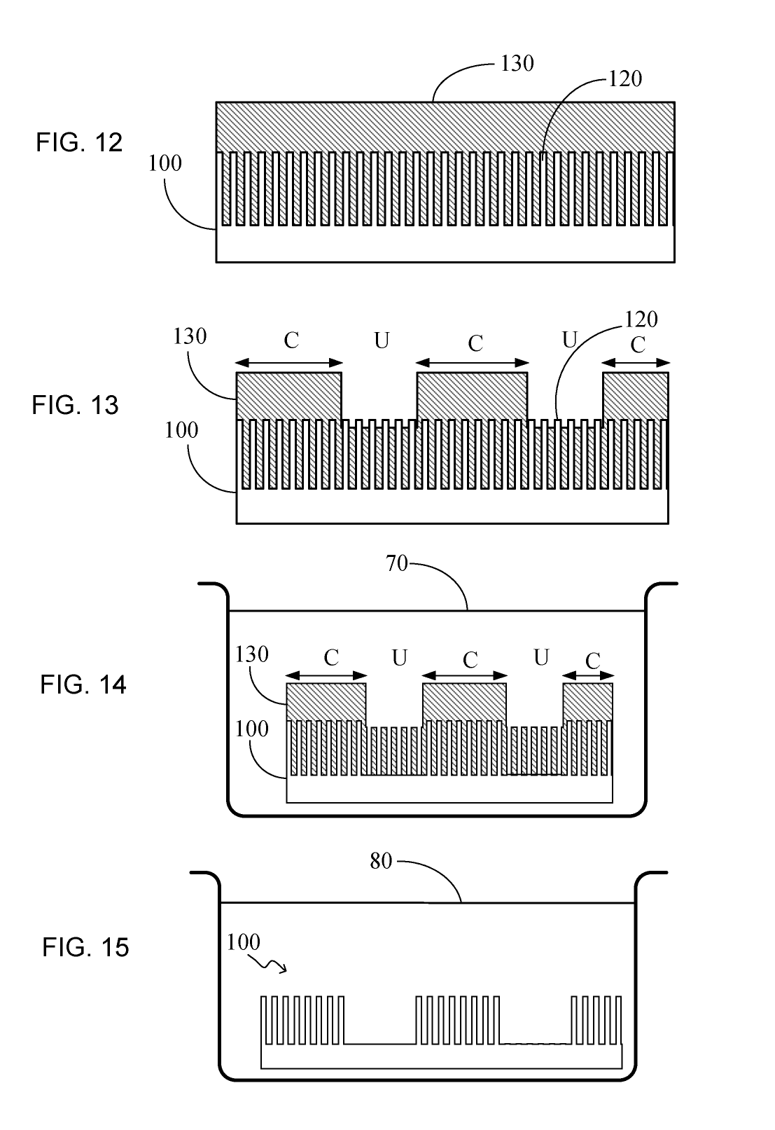

Referring to FIG. 11 and FIG. 12, FIG. 12 is a schematic section view illustrating the array 100 of silicon nanowire structures in performing step S23. At step S23, a photoresist layer is coated over the array 100 of silicon nanowire structures, in which space between the silicon nanowires 120 is filled with the photoresist layer 130.

Referring to FIG. 11 and FIG. 13, FIG. 13 is a schematic section view illustrating the array 100 of silicon nanowire structures in performing step S24. At step S24, the photoresist layer 130 is patterned, so that the array 100 of silicon nanowire structures have the photoresist layer on the covered region C, and expose the silicon nanowires 120 on the uncovered region U. Specifically, the step of patterning the photoresist layer 130 may include conventional ultra-violet (UV) exposure and development processes, so no further detail will be provided herein. It is worth mentioning that the array 100 of silicon nanowire structures have an excellent light absorbing property during the UV exposure process; thus, only top portions of the silicon nanowires 120 on the uncovered region U are exposed after the development process.

Referring to FIG. 1 again, at step S30, a selective etching is employed to remove the array 100 of silicon nanowire structures defined on the uncovered region U. Referring to FIG. 14, FIG. 14 is a schematic section view illustrating the array 100 of silicon nanowire structures in performing step S30 according to the second preferred embodiment. In the second preferred embodiment, the step of the selective etching includes: to immerse the array 100 of silicon nanowire structures which have the photoresist layer 130 in an aqueous solution 70 containing hydrofluoric acid and nitric acid, so as to etch the silicon nanowires 120 exposed on the uncovered region U of the array 100 of silicon nanowire structures. It is worth mentioning that the silicon nanowires 120 exposed on the uncovered region U are gradually etched from top to bottom thereof.

Referring to FIG. 1 and FIG. 10, at step S40, the patterned protective layer remained on the array 100 of silicon nanowire structures is removed. Referring to FIG. 15, FIG. 15 is a schematic section view illustrating the array 100 of silicon nanowire structures in performing step S40 according to the second preferred embodiment. In the second preferred embodiment, the array 100 of silicon nanowire structures is immersed in an acetone solution 80 to remove the remaining photoresist layer 130, thereby completing the patterned silicon nanowire array.

The following will explain a method for fabricating heterostructures on the patterned silicon nanowire array according to a preferred embodiment of the present invention in detail with drawings. In the embodiment, the heterostructures are carbon nanotubes. However, the present invention is not limited to be implemented in the carbon nanotubes; other manners, such as growing the polycrystalline silicon on the patterned silicon nanowire array, are within the scope of the present invention.

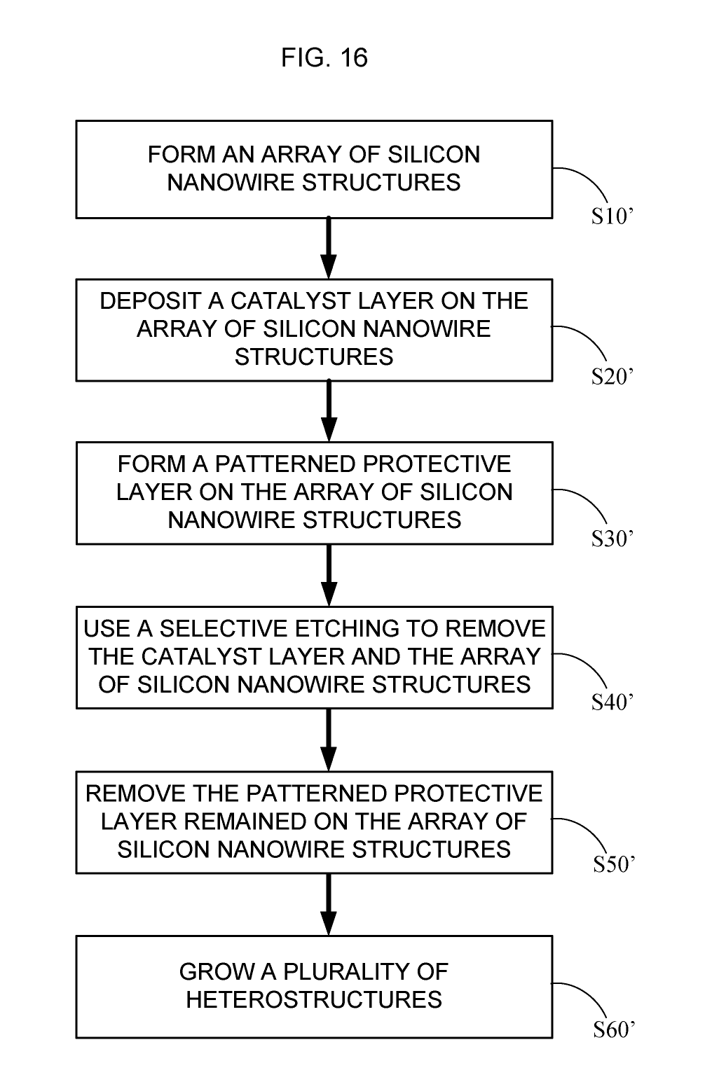

Referring to FIG. 16, FIG. 16 depicts a flow chart illustrating a fabrication method of forming the heterostructures on the patterned silicon nanowire array according to the preferred embodiment of the present invention. The fabrication method of the embodiment begins with step S10′. At step S10′, the array of silicon nanowire structures is being formed. The specific steps can refer to the above-mentioned description of FIG. 2, so no further detail will be provided herein.

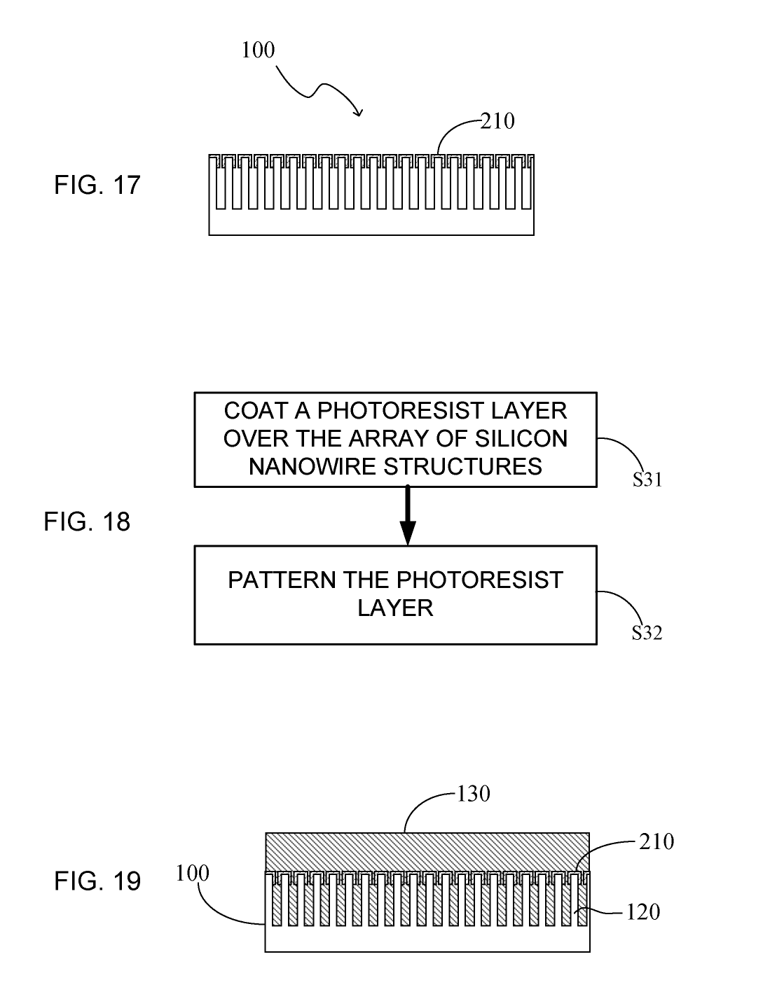

At step S20′, a catalyst layer 210 are deposited on the array 100 of silicon nanowire structures. Referring to FIG. 17, FIG. 17 is a schematic section view illustrating the array 100 of silicon nanowire structures in performing step S20′. In the embodiment, the catalyst layer 210 can be the catalyst which used for growing the carbon nanotubes. Preferably, it can be aluminum and iron particles. Referring to FIG. 17, because the silicon nanowires are arranged very closely, the catalyst layer 210 is just formed on the tops of the silicon nanowires 120 of the array 100 of silicon nanowire structures.

At step S30′, a patterned protective layer is formed on the array 100 of silicon nanowire structures having the catalyst layer 210. Referring to FIG. 18, FIG. 18 is a flow chart illustrating processes of forming the patterned protective layer according to the preferred embodiment; the step of forming the patterned protective layer begins with step S31. Referring to FIG. 19, FIG. 19 is a schematic section view illustrating the array 100 of silicon nanowire structures in performing step S31. At step S31, the photoresist layer 130 is coated over the array 100 of silicon nanowire structures having the catalyst layer 210, in which the space between the silicon nanowires 120 is filled with the photoresist layer 130.

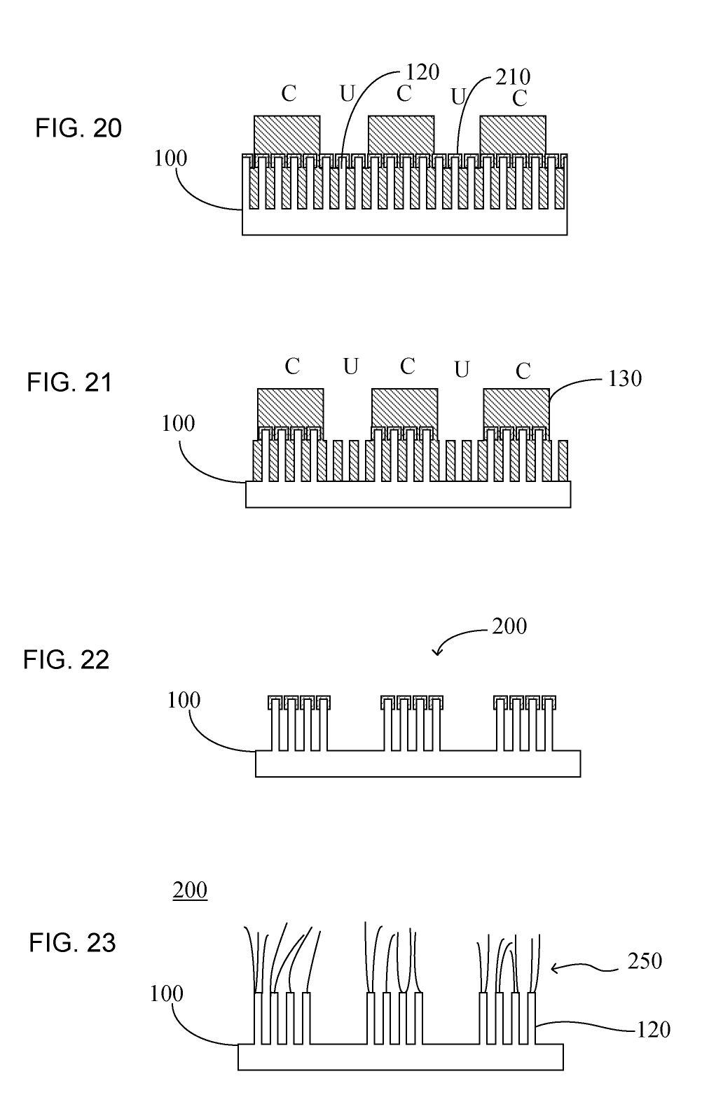

Referring to FIGS. 18 and 20, FIG. 20 is a schematic section view illustrating the array 100 of silicon nanowire structures in performing step S32. At step S32, the photoresist layer 130 is patterned, so that the array 100 of silicon nanowire structures has the photoresist layer on the covered region C, and exposes the silicon nanowires 120 having the catalyst layer 210 on the uncovered region U.

Referring to FIG. 16 again, at step S40′, a selective etching is employed to remove the catalyst layer 210 and the array 100 of silicon nanowire structures defined on the uncovered region U. Referring to FIG. 21, FIG. 21 is a schematic section view illustrating the array 100 of silicon nanowire structures in performing step S40′ according to the preferred embodiment. In the preferred embodiment, the step of the selective etching includes: to remove the catalyst layer positioned on the uncovered region 210; and to immerse the array 100 of silicon nanowire structures which have the photoresist layer 130 in the aqueous solution containing hydrofluoric acid and nitric acid, so as to etch the silicon nanowires 120 exposed on the uncovered region U of the array 100 of silicon nanowire structures.

Referring to FIG. 16 again, at step S50′, the patterned protective layer remained on the array 100 of silicon nanowire structures is removed to form the patterned silicon nanowire array. Referring to FIG. 22, FIG. 22 is a schematic section view illustrating the array 100 of silicon nanowire structures in performing step S50′ according to the preferred embodiment. Similarly, the array 100 of silicon nanowire structures is immersed in the acetone solution 80 to remove the remaining photoresist layer 130, thereby completing the patterned silicon nanowire array 200.

Referring to FIG. 16 again, at step S60′, a plurality of heterostructures are grown on the patterned silicon nanowire array 200. Referring to FIG. 23, FIG. 23 is a schematic section view illustrating the array 100 of silicon nanowire structures in performing step S60′ according to the preferred embodiment. In the embodiment, the heterostructures are a plurality of carbon nanotubes 250, and the carbon nanotubes grow through thermal chemical vapor deposition (thermal CVD). It should be noted that the number of the carbon nanotubes 250 on each silicon nanowire 120 can be one or more. It is worth mentioning that the structure of the carbon nanotubes forming on the patterned silicon nanowire array of the present invention can help decrease a driving voltage of the field emission.

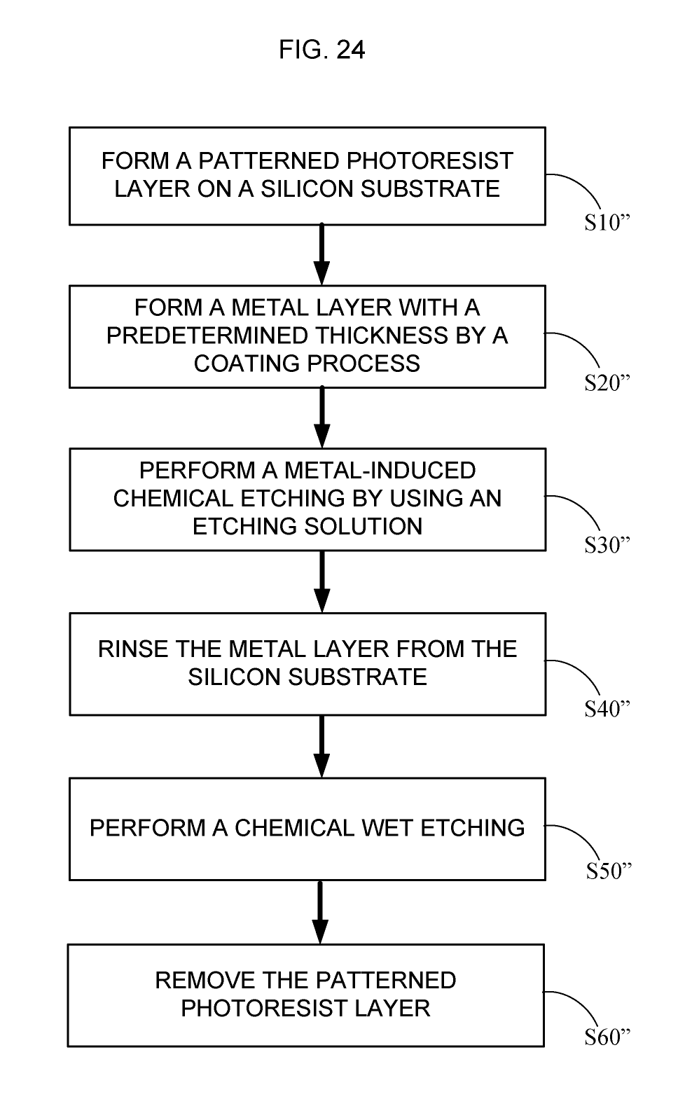

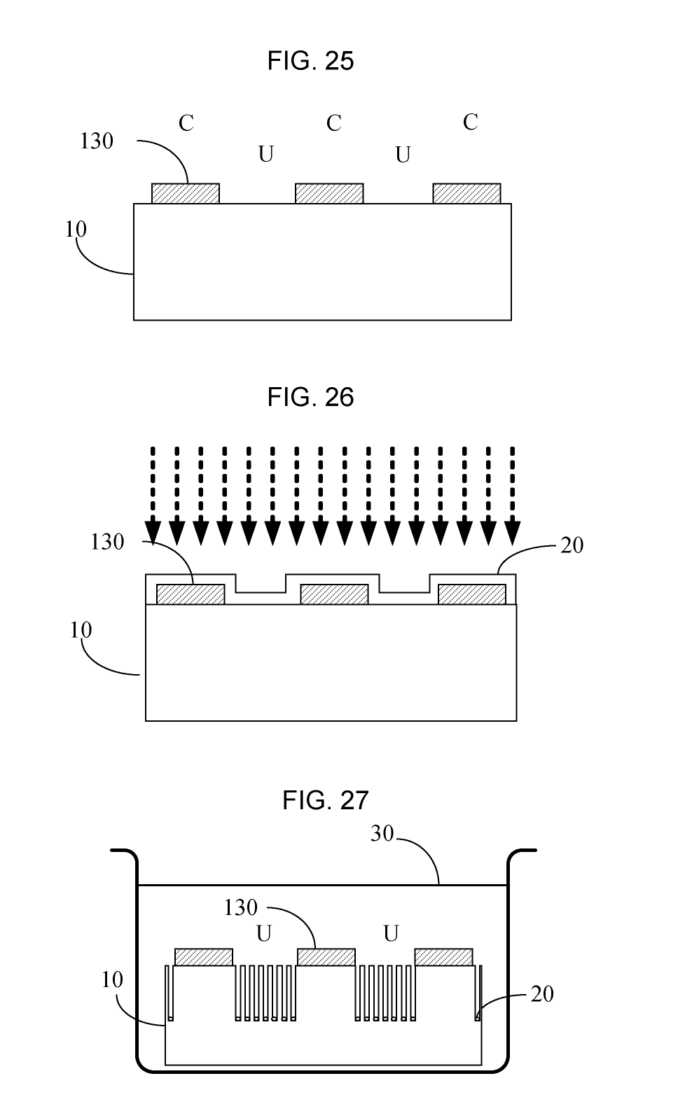

The following will explain a method for fabricating a silicon microstructure according to a preferred embodiment of the present invention in detail with drawings. Referring to FIGS. 24 and 25, FIG. 24 is a flow chart illustrating a method for fabricating a silicon microstructure according to one preferred embodiment of the present invention; FIG. 25 is a schematic section view illustrating a silicon substrate in performing step S10″. The fabrication method of the embodiment begins with step S10″.

At step S10″, a patterned photoresist layer 130 is formed on silicon substrate 10, and the covered region C and uncovered region U can be formed on the silicon substrate 10 by the patterned photoresist layer 130. It should be noted that the silicon substrate 10 can be a substrate which has a silicon layer on the surface thereof. The silicon material can be monocrystalline silicon, which has a lattice plane of 100, 110, or 111, for example. The silicon material also can be polycrystalline silicon or amorphous silicon (a-Si); moreover, the silicon material is intrinsic silicon or doped silicon. In the embodiment, the silicon substrate 10 is made of monocrystalline silicon which has a lattice plane of 100. Specifically, the manner of forming patterned photoresist layer 130 includes the conventional photolithography process, so no further detail will be provided herein.

Referring to FIGS. 24 and 26, FIG. 26 is a schematic section view illustrating the silicon substrate in performing step S20″. At step S20″, a metal layer with a predetermined thickness 20 is formed on the silicon substrate 10 having the patterned photoresist layer 130 by a coating process. The metal layer 20 is selected from the group consisting of silver, gold, and platinum, in which the silver (Ag), gold (Au), and platinum (Pt) are metal having a catalytic effect for silicon. Similarly, the coating process can be electron beam evaporation, physical vapor deposition, chemical vapor deposition, sputtering, and so on. In the preferred embodiment, the metal layer is silver, and the predetermined thickness of the metal layer 20 is between 5 nm and 50 nm In the preferred embodiment, the best thickness of the metal layer 20 is 20 nm.

Referring to FIGS. 24 and 27, FIG. 27 is a schematic section view illustrating the silicon substrate in performing step S30″. At step S30″, an etching solution 30 is utilized to perform a metal-induced chemical etching for the silicon substrate 10 positioned on the uncovered region U. Specifically, the etching solution 30 can be the aqueous solution of hydrogen fluoride (HF) and hydrogen peroxide (H₂O₂). Because the thickness of the metal layer 20 is ultra thin (5 nm to 50 nm), the etching solution 30 can easily be infiltrated to the surface of the silicon substrate 10. Furthermore, the silicon substrate 10 is partially etched down through the catalyst of the silver at the area on which the silver is located, and the area uncovered by the silver is not etched down. The hydrogen peroxide (H₂O₂) is utilized to oxidize the silicon to form silicon dioxide (SiO₂), and then the hydrofluoric acid etches the silicon dioxide (SiO₂), thereby etching down.

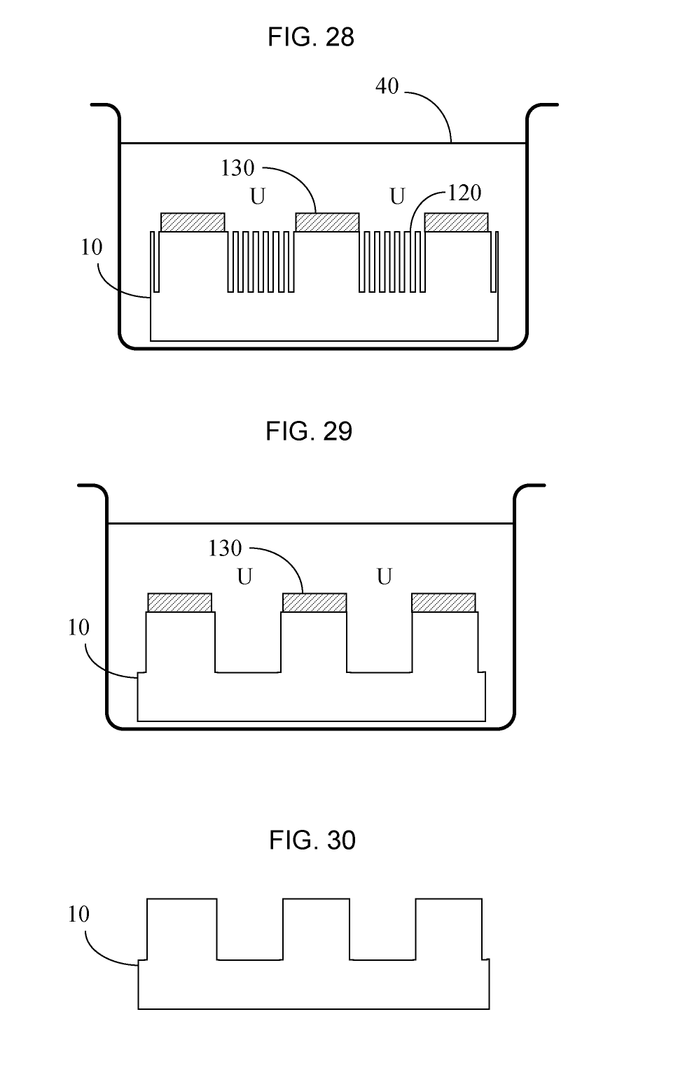

Referring to FIGS. 24 and 28, FIG. 28 is a schematic section view illustrating the silicon substrate in performing step S40″. At step S40″, the metal layer 20 is rinsed from the silicon substrate 10 forming the silicon nanowire array on the uncovered region U. For example, the remaining silver can be washed away by using nitric acid (HNO₃) solution 40.

Referring to FIGS. 24 and 29, FIG. 29 is a schematic section view illustrating the silicon substrate in performing step S50″. At step S50″, a chemical wet etching is performed, so as to remove the silicon nanowire array, i.e. the silicon nanowires 120, formed on the uncovered region. The chemical wet etching is a process of using suitable etching solution to remove the silicon nanowires 120. Specifically, the etching solution can be the aqueous solution containing hydrofluoric acid and nitric acid.

Referring to FIGS. 24 and 30, FIG. 30 is a schematic section view illustrating the silicon substrate in performing step S60″. At step S60″, the patterned photoresist layer 130 is removed, e.g. by immersing it into the acetone solution to remove the remaining photoresist layer 130, thereby completing the fabrication of the silicon microstructures.

In summary, In accordance with the fabrication method of the patterned silicon nanowire arrays of the present invention, the oxide layer 110 or the patterned protective layer implemented by the photoresist layer 130 is directly formed on the surfaces of the array 100 of silicon nanowire structures, and then the silicon nanowires 120 which are not protected are etched by the wet etching manner, thereby easily and low-costly manufacturing the patterned silicon nanowire array. In addition, the present invention is further capable of forming the heterostructures, e.g. growing the carbon nanotubes 250, on said patterned silicon nanowire array for applying to the field emission applications. Finally, the present invention is capable of forming the silicon nanowire array on the selective area of the silicon substrate 10 and then etching the silicon nanowires 120 for achieving the objective that the silicon microstructures with the vertical sidewalls can be made by wet etching for any silicon substrate, especially for the (100) monocrystalline silicon.

While the preferred embodiments of the present invention have been illustrated and described in detail, various modifications and alterations can be made by persons skilled in this art. The embodiment of the present invention is therefore described in an illustrative but not restrictive sense.

What is claimed is:

1. A method for fabricating a patterned silicon nanowire array, the method comprising:
forming an array of silicon nanowire structures;
forming a patterned protective layer on the array of silicon nanowire structures, the patterned protective layer defining a covered region and a uncovered region on the array of silicon nanowire structures;
using a selective etching to remove the array of silicon nanowire structures defined on the uncovered region; and
removing the patterned protective layer remained on the array of silicon nanowire structures.

2. The method of claim 1, wherein the step of forming the array of silicon nanowire structures comprises:
forming a metal layer with a predetermined thickness on a silicon substrate by a coating process;
performing a metal-induced chemical etching for the silicon substrate by using an etching solution;
rinsing the metal layer from the silicon substrate.

3. The method of claim 1, wherein the step of forming the patterned protective layer comprises:
oxidizing the array of silicon nanowire structures forming an oxide layer on a surface of the array of silicon nanowire structures; and
patterning the oxide layer so that the array of silicon nanowire structures have the oxide layer on the covered region and expose a plurality of silicon nanowires on the uncovered region.

4. The method of claim 3, wherein the step of oxidizing the array of silicon nanowire structures comprises:
immersing the array of silicon nanowire structures in a nitric acid solution.

5. The method of claim 3, wherein the step of patterning the oxide layer comprises a photolithography process.

6. The method of claim 3, wherein the step of the selective etching comprises:
immersing the array of silicon nanowire structures which have the oxide layer in a potassium hydroxide (KOH) solution, so as to etch the silicon nanowires exposed on the uncovered region of the array of silicon nanowire structures.

7. The method of claim 3, wherein the KOH solution comprises about 60% by weight of potassium hydroxide at room temperature.

8. The method of claim 1, wherein the step of forming the patterned protective layer comprises:
coating a photoresist layer over the array of silicon nanowire structures, wherein space between a plurality of silicon nanowires is filled with the photoresist layer; and
patterning the photoresist layer so that the array of silicon nanowire structures have the photoresist layer on the covered region and simultaneously expose the silicon nanowires on the uncovered region.

9. The method of claim 8, wherein the step of patterning the photoresist layer comprises an exposure process and a development process.

10. The method of claim 8, wherein the step of the selective etching comprises:
immersing the array of silicon nanowire structures which have the photoresist layer in an aqueous solution containing hydrofluoric acid and nitric acid, so as to etch the silicon nanowires exposed on the uncovered region of the array of silicon nanowire structures.

11. A method for fabricating heterojunctions on a patterned silicon nanowire array, comprising:
forming an array of silicon nanowire structures;
depositing a catalyst layer on the array of silicon nanowire structures;
forming a patterned protective layer on the array of silicon nanowire structures having the catalyst layer, the patterned protective layer defining a covered region and a uncovered region on the array of silicon nanowire structures;
using a selective etching to remove the catalyst layer and the array of silicon nanowire structures defined on the uncovered region;
removing the patterned protective layer remained on the array of silicon nanowire structures to form the patterned silicon nanowire array; and
growing a plurality of heterostructures on the patterned silicon nanowire array.

12. The method of claim 11, wherein the step of forming the array of silicon nanowire structures comprises:
forming a metal layer with a predetermined thickness on a silicon substrate by a coating process;
performing a metal-induced chemical etching for the silicon substrate by using an etching solution; and
rinsing the metal layer from the silicon substrate.

13. The method of claim 11, wherein the catalyst layer is just formed on tops of a plurality of silicon nanowires of the array of silicon nanowire structures.

14. The method of claim 13, wherein the step of forming the patterned protective layer comprises:
coating a photoresist layer over the array of silicon nanowire structures having the catalyst layer, wherein space between the silicon nanowires is filled with the photoresist layer; and
patterning the photoresist layer so that the array of silicon nanowire structures have the photoresist layer on the covered region and simultaneously expose the silicon nanowires having the catalyst layer on the uncovered region.

15. The method of claim 14, wherein the step of the selective etching comprises:
removing the catalyst layer positioned on the uncovered region; and
immersing the array of silicon nanowire structures which have the photoresist layer in an aqueous solution containing hydrofluoric acid and nitric acid, so as to etch the silicon nanowires exposed on the uncovered region of the array of silicon nanowire structures.

16. The method of claim 13, wherein the heterostructures are a plurality of carbon nanotubes, and the carbon nanotubes grow through a thermal chemical vapor deposition.

17. A method for fabricating a silicon microstructure, comprising:
forming a patterned photoresist layer on a silicon substrate, the patterned photoresist layer having a covered region and a uncovered region on the silicon substrate;
forming a metal layer with a predetermined thickness on the silicon substrate having the patterned photoresist layer by a coating process;
performing a metal-induced chemical etching for the silicon substrate positioned on the uncovered region by using an etching solution;
rinsing the metal layer from the silicon substrate for forming a silicon nanowire array on the uncovered region; and
performing a chemical wet etching to remove the silicon nanowire array formed on the uncovered region.

18. The method of claim 17, wherein the predetermined thickness is between 5 and 50 nanometers.

19. The method of claim 17, wherein the silicon substrate is made of monocrystalline silicon, polycrystalline silicon, or amorphous silicon.

20. The method of claim 19, wherein the silicon substrate is made of monocrystalline silicon which has a lattice plane of 100.
